(19) United States
(12) Patent Application Publication
(10) Pub. No.: US 2026/0176762 A1
(43) Pub. Date: Jun. 25, 2026

(54) PROCESS FOR MANUFACTURING A SOLID ELECTROLYTE FOR AN ELECTROCHEMICAL DEVICE

(71) Applicant: Commissariat à l'Energie Atomique et aux Energies Alternatives, Paris (FR)

(72) Inventors: Ilyass GHANDARI, Grenoble cedex 09 (FR); Messaoud BEDJAOUI, Grenoble cedex 09 (FR); Sylvain POULET, Grenoble cedex 09 (FR)

(73) Assignee: Commissariat à l'Energie Atomique et aux Energies Alternatives, Paris (FR)

(21) Appl. No.: 19/426,626

(22) Filed: Dec. 19, 2025

(30) Foreign Application Priority Data
Dec. 20, 2024 (FR) FR2414857

(51) Int. Cl. C23C 16/455; C23C 16/30; C23C 16/44; H01M 10/0562

(52) U.S. Cl. CPC C23C 16/45555; C23C 16/308; C23C 16/4408; H01M 10/0562; H01M 2300/0068

(57) ABSTRACT

A method for manufacturing a solid electrolyte, including: (a) disposing a substrate in the reaction chamber of an atomic thin film deposition reactor; (b) providing a pulse of a first chemical precursor in the reaction chamber; (c) purging the reaction chamber; (d) providing a pulse of a second chemical precursor in the reaction chamber; (e) purging the reaction chamber; (f) repeating steps (d) and (e) with another chemical precursor; (g) repeating steps (b) to (e) or, when step (f) is performed, steps (b) to (f), until a desired thickness of the solid electrolyte is obtained. The manufacturing process further comprises a step (h) consisting in providing a pulse of an inert gas for a determined time in the reaction chamber.

The present invention concerns devices in the field of energy storage by electrochemical means, and more particularly the manufacture of a solid electrolyte for electrochemical energy storage devices such as micro-supercapacitors in order to improve their electrochemical performance.

The improvement of the miniaturization of passive components, particularly micro-supercapacitors which are equipped with two electrodes (electrical conductors) separated by a solid electrolyte (ionic conductor), constitutes one of the main challenges faced by the power microelectronics industry. Indeed, solid electrolytes are an essential component of these micro-devices, which must meet several technological challenges, including energy storage, backup power, and the extension the lifetime of such micro-devices.

These technological challenges are addressed thanks to the mobility of charge carriers (for example Li⁺, Na⁺, K⁺) within the solid electrolyte. As a result, an increased ionic conductivity enables an efficient energy storage and a charging and discharging time in the range of microseconds.

Furthermore, the growing need for solid electrolyte including a complex three-dimensional geometric structure requires the meticulous development of their manufacturing process through successive depositions of ultrathin layers with a perfectly controlled chemical composition, regardless of the dimensions and architecture of the manufacturing supports. Therefore, conventional prior art techniques for manufacturing solid electrolytes are not always suited to current technical constraints, including in particular the deposition of ultrathin layers in structures with complex geometries.

Atomic Layer Deposition (ALD) technique is a preferred technique for meeting these needs. Indeed, it allows for the fabrication of thin films that perfectly conform to current requirements for the solid electrolytes, with a rigorous thickness control as well as an atomic-scale uniformity.

ALD relies on the sequential chemisorption of chemical precursors in a self-limiting manner, allowing the formation of atomic layers superimposed on one another until a layer of desired thickness is obtained.

More specifically, an ALD reactor is fed with chemical precursors in gaseous or liquid form which are typically heated to vaporize them and transport them using an inert gas (for example argon) to the reaction chamber of the ALD reactor.

It is thus perfectly known to manufacture a solid electrolyte in an ALD reactor from at least two chemical precursors by repeating a cycle comprising the following steps until the desired thickness of said electrolyte is obtained.

A 1^{st} step during which a 1^{st} chemical precursor is introduced into the reaction chamber of the ALD reactor, which comprises a substrate and where it reacts chemically with the active sites on the surface of said substrate during a 1^{st} chemical reaction in such a way that it forms a 1^{st} part of an atomic layer which includes active sites. Since ALD relies on chemisorption, each molecule of the 1^{st} chemical precursor reacts with the active sites until the surface of the substrate is saturated. Once all the reactive sites are occupied by molecules of the 1^{st} precursor, no additional molecules of the 1^{st} precursor can be adsorbed, making this 1^{st} step self-limiting.

A 2^{nd} purge step during which the pumping device with which the ALD reactor is equipped purges the excess of the 1^{st} chemical precursor and/or by-products of this 1^{st} chemical reaction in order to clean the reaction chamber before the introduction of a 2^{nd} chemical precursor.

A 3^{rd} step during which a 2^{nd} chemical precursor is introduced into the reaction chamber, where it reacts chemically with the active sites of the 1^{st} part of the atomic layer during a 2^{nd} chemical reaction in such a way that it forms a 2^{nd} part of the atomic layer which includes active sites. This 2^{nd} chemical reaction contributes to the formation of a 2^{nd} part of the atomic layer, or even completes the formation of the atomic layer if the cycle is implemented with only two chemical precursors.

A 4th purge step during which the pumping device purges the excess of the 2^{nd} chemical precursor and/or by-products of this 2^{nd} chemical reaction in order to clean the reaction chamber before the introduction of another chemical precursor (namely, again the 1^{st} chemical precursor when the cycle implements two chemical precursors and it is therefore the restart of the cycle or a 3^{rd} chemical precursor when the cycle continues with a 3^{rd} chemical precursor).

Thus, the cycle may comprise the implementation of other steps that are similar to the 3^{rd} and 4^{t}h steps with other chemical precursors.

Generally, the cycle comprises the implementation of two, or even three, different chemical precursors.

In this regard, WO 2013/011297 A1 describes a process for forming a lithium-containing thin film at the surface of a substrate which implements a lithium precursor. Steps c) and e) of this process are steps of purging the reaction chamber.

The thickness of an atomic layer is in the range of an Angstrom.

The geometry of the substrate plays a crucial role in improving the properties of atomic layers deposited by ALD. For planar (i.e., two-dimensional) substrates, the active surface area is indeed essentially limited to the flat surface of the substrate, offering a fixed number of sites available for the adsorption of the chemical precursors. However, for three-dimensional substrates, the active surface area is considerably increased due to the complexity of the topography of the substrate, often in the form of nano-structures or pores.

Increasing the active surface area of three-dimensional substrates allows for more optimized ALD deposition of the chemical precursors, as they can react over a larger surface area. This increased surface area makes it possible to improve the performance of the solid electrolyte due to this enhanced interaction between the chemical precursors and the substrate, contributing to improved ionic conductivity and higher charge density.

In summary, the ALD technique is particularly suitable for manufacturing a solid electrolyte on a three-dimensional substrate.

In order to optimize the ionic mobility of the solid electrolyte by increasing the incorporation of the aforementioned charge carriers (for example Li⁺, Na⁺, K⁺), one solution may be to increase the thermal budget of the manufacture of a solid electrolyte by ALD.

In the context of the present invention, “thermal budget” means the supply of energy of a thermal nature during the manufacture of said solid electrolyte.

Indeed, the surface reactions that occur during the steps of adsorbing the chemical precursors are subject to activation energies. This means that a certain level of thermal energy is required to overcome energy barriers and make it possible to initiate the chemical reactions. A higher thermal budget therefore allows the molecules of the chemical precursors to reach a sufficient energy to overcome the energy barriers of the surface reactions. This facilitates a better incorporation of the atoms and more efficient growth of the solid electrolyte. This increased thermal budget is thus highly favorable to the incorporation of the ionic elements and, consequently, to the ionic transport properties of the solid electrolytes.

However, when seeking to increase the thermal budget, care must be taken to ensure that raising the temperature in the reaction chamber of the ALD reactor does not induce the thermal decomposition of the chemical precursors; this would lead to incomplete saturation of the surface of the substrate, and therefore to obtaining a non-conforming solid electrolyte, particularly when the substrate has a complex three-dimensional geometry.

Given the drawback of the risk of excessively high temperatures in the reaction chamber which could decompose the chemical precursors, the inventors sought to increase the thermal budget during the manufacture of a solid electrolyte in a way other than by raising the temperature in order to avoid the risk of degrading the nature of the chemical precursors and to obtain a more efficient solid electrolyte with regard to its ionic conductivity.

The inventors have developed a process for manufacturing a solid electrolyte that perfectly fulfills all these objectives.

Therefore, the invention relates to a process for manufacturing a solid electrolyte which comprises at least the following steps:
a) disposing a substrate comprising active sites on its surface in the reaction chamber of an ALD reactor;
b) providing a pulse of a 1^{st} chemical precursor which is in gaseous form in the reaction chamber such that the 1^{st} chemical precursor reacts with the active sites of the substrate during a 1^{st} chemical reaction and a 1^{st} part of an atomic layer which includes active sites is formed;
c) purging the reaction chamber of the 1^{st} chemical precursor and any by-products of the 1^{st} chemical reaction;
d) providing a pulse of a 2^{nd} chemical precursor which is in gaseous form in the reaction chamber such that the 2^{nd} chemical precursor reacts with the active sites of the 1^{st} part of the atomic layer during a 2^{nd} chemical reaction and a 2^{nd} part of the atomic layer which includes active sites is formed;
e) purging the reaction chamber of the 2^{nd} chemical precursor and any by-products of the 2^{nd} chemical reaction;
f) repeating, optionally, steps d) and e) with at least one other chemical precursor;
g) repeating, optionally, steps b) to e), or, where appropriate when step f) is carried out, steps b) to f),
until a desired thickness of the solid electrolyte is obtained;
said process is characterized in that it further comprises carrying out at least once a step h) which consists in providing a pulse of an inert gas during a determined time in the reaction chamber.

In the process for manufacturing a solid electrolyte according to the invention, step h) is not a purge step. Step h) is clearly distinct from steps c) and e) of purging the reaction chamber. Furthermore, step h) is a step different from steps c) and e) of the process for forming a thin layer described in application WO 2013/011297 A1 mentioned above.

Thus, with the process for manufacturing a solid electrolyte according to the invention, the increased thermal budget for manufacturing the solid electrolyte is obtained without raising the temperature of depositing the chemical precursors, but rather by increasing their residence time in the reaction chamber. Consequently, the thermal budget to which the solid electrolyte is exposed during manufacturing is increased while maintaining a self-limiting growth regime, particularly well-suited to the solid electrolytes having a complex three-dimensional geometric structure. Increasing the residence time of the chemical precursors in the reaction chamber allows for better diffusion of the latter within the substrates, especially three-dimensional substrates, namely substrates having complex architectures (hollows and/or bumps).

In other words, with the process for manufacturing a solid electrolyte according to the invention, the thermal exposure time of the atomic layers during their formation is increased. Such an approach is akin to a growth mode based on the deposition of atomic layers combined with in-situ thermal densification. The atomic layers thus synthesized have better incorporation of mobile charge-carrying ions (such as Li⁺, Na⁺, K⁺), making it possible thus to obtain a solid electrolyte with higher ionic conductivity. The process for manufacturing a solid electrolyte according to the invention provides an enrichment in ionic elements, making it possible to improve the ionic properties of said solid electrolyte.

The improvement in the ionic conductivity of the thin-layer electrolyte is thus correlated with step h).

Step h) must be carried out at least once during the manufacturing process according to the invention. In other words, step h) can be carried out once or several times during the manufacturing process according to the invention.

The inert gas of step h) can be selected from nitrogen and argon.

The duration of step h) can be comprised between 10 seconds and 500 seconds, for example, 100 seconds. Step h) can be performed multiple times. At each repetition of step h), the duration of this step h) can be comprised between 10 seconds and 500 seconds, for example, 100 seconds.

When step h) is carried out several times:
the inert gas may be different from one time to another;
the duration of step h) may vary from one time to another.

Since step h) can be carried out once or several times during the manufacturing process according to the invention, said manufacturing process may have at least one of these technical characteristics which are detailed below, taken alone or in combination:
step h) can be performed before step b);
step h) can be performed after completion of all the purge steps or only a part of said purge steps;
step h) can be performed after the completion of all the steps in which a chemical precursor pulse is provided or of only a part of the steps in which a chemical precursor pulse is provided.

When step h) is performed after the completion of all the purge steps, this means that said step h) is systematically performed after each purge step. The purge steps correspond to steps c) and e) of the manufacturing process according to the invention.

When step h) is performed after the completion of part of the purge steps, this means that said step h) is performed after the completion of at least one of the purge steps which are carried out during the manufacturing process according to the invention.

When step h) is performed after the completion of all steps during which a chemical precursor pulse is provided, this means that said step h) is systematically performed after each step during which a chemical precursor pulse is provided. These steps are steps b) and d) of the manufacturing process according to the invention.

When step h) is performed after the completion of part of the steps during which a chemical precursor pulse is provided, this means that said step h) is performed after the completion of at least one step during which a chemical precursor pulse is provided.

In one embodiment of the invention, step h) can be performed after all the steps of said manufacturing process where a pulse of a chemical precursor is provided and after all the purge steps.

In one embodiment of the invention, step h) can be performed:
before step b), as well as
after all the steps of said manufacturing process during which a pulse of a chemical precursor is provided and after all the purge steps.

In one embodiment of the invention, step h) can be performed only after all the purge steps.

In one embodiment of the invention, step h) can be performed:
before step b), as well as
after all the purge steps.

In one embodiment of the invention, step h) can be performed only after all the steps during which a chemical precursor pulse is provided.

In one embodiment of the invention, step h) can be performed:
before step b), as well as
after all the steps during which a chemical precursor pulse is provided.

In another embodiment of the invention, step h) can be performed only before the completion of step b).

In one embodiment of the invention, step h) can only be performed at the end of the last purge step of the manufacturing process according to the invention.

The material of the substrate can advantageously be a thermally stable material that is capable of accommodating deposits at temperatures that can, for example, be comprised between 100° C. and 500° C.

The material of the substrate can be selected from titanium, platinum, nickel, ruthenium, copper, glass, silicon and silicon carbide.

The material of the substrate can, for example, be a silicon wafer, a glass wafer, or a silicon carbide wafer.

The substrate can be a planar substrate (in other words, a two-dimensional substrate) or a three-dimensional substrate.

Considering the advantages detailed above, the substrate is preferably three-dimensional. In other words, the substrate can have a complex three-dimensional structure. The substrate can thus have a high aspect ratio. This means that the substrate can have hollows and bumps.

In one embodiment of the invention, the substrate can be partly planar and partly three-dimensional.

The thickness of the substrate can be comprised between 100 μm and 1000 μm.

As explained above, optionally, steps d) and e) are repeated with at least one other chemical precursor. This means that the process for manufacturing a solid electrolyte according to the invention can be implemented with more than 2 different chemical precursors. Between 2 and 4 different chemical precursors can be implemented during the process for manufacturing a solid electrolyte according to the invention. Preferably, between 2 and 3 different chemical precursors are implemented. Most preferably, 2 different chemical precursors are implemented.

The material of the solid electrolyte can be selected from nitrided lithium phosphates (abbreviated “LiPON”), nitrided sodium phosphates (abbreviated “NaPON”), nitrided potassium phosphates (abbreviated “KPON”) and nitrided magnesium phosphates (abbreviated “MgPON”).

In a preferred embodiment of the invention, the material of the solid electrolyte is a LiPON.

In this embodiment of the invention, the manufacturing process can be implemented with the following chemical precursors:
a 1^{st} chemical precursor which is a source of lithium and which can be selected from lithium hexamethyldisilazane (abbreviated “LiHMDS”), lithium tert-butylate (abbreviated “LiOtBu”) and lithium diethylamide (abbreviated “LiN(C₂H₅)₂”);
a 2^{nd} chemical precursor which is a source of at least one element selected from phosphorus, oxygen and nitrogen and which can be selected from diethyl phosphoramidate (abbreviated “DEPA”), trimethyl phosphate (abbreviated “TMPO”), tris(dimethylamino)phosphine (abbreviated “TDMAP”), ammonia and water.

Solid electrolyte materials analogous to LiPON can be NaPON, KPON, and MgPON. These materials can be obtained via chemical precursors of alkali tert-butoxides (Li, Na, K, Mg) as the 1^{st} chemical precursor and DEPA as the 2^{nd} chemical precursor. Therefore, by implementing step h) at least once during the manufacturing process according to the invention, it is possible to achieve a higher incorporation of sodium or potassium into the electrolytic layers, thereby increasing the ionic conductivities in these solid electrolytes analogous to LiPON.

Depending on the desired solid electrolyte material, it is perfectly within the reach of a person skilled in the art to select the appropriate chemical precursors to manufacture the solid electrolyte according to the manufacturing process according to the invention.

The chemical precursors can be stored in gaseous form or in liquid form.

When the chemical precursors are stored in liquid form, they can be heated so that they can be injected in gaseous form into the reaction chamber. Implementing the heating of the chemical precursors so as to allow for their injection in gaseous form into the reaction chamber is perfectly feasible for a person skilled in the art.

In one embodiment of the invention, the chemical precursors can be stored in bubblers at a temperature which can be comprised between 60° C. and 100° C. For example, LiHMDS can be stored in a bubbler at a temperature comprised between 60° C. and 80° C. and DEPA can be stored in a bubbler at a temperature comprised between 80° C. and 100° C.

The chemical precursors can be introduced (i.e., in the form of a pulse) into the reaction chamber of the ALD reactor using an inert gas. The inert gas can be selected from argon and nitrogen. In other words, the chemical precursors can be transported into the reaction chamber using an inert gas.

During steps c) and e), the reaction chamber can be purged using an inert gas (for example, a gas selected from argon and nitrogen). During these purge steps c) and e), the pumping device of the ALD reactor is activated to purge excess chemical precursors and any by-products of the chemical reaction that has just taken place in the reaction chamber.

Step h) of the manufacturing process according to the invention is a step clearly distinct from the purge steps c) and e). Indeed, during step h), the pumping device of the ALD reactor is not activated, so there is no purging of the chemical precursors and chemical reaction by-products possibly present in the reaction chamber at the time of the completion of step h).

The temperature of the reaction chamber can be appropriately selected based on the chemical precursors implemented during the process for manufacturing a solid electrolyte according to the invention. Determining this appropriate temperature of the reaction chamber is perfectly within the capabilities of a person skilled in ALD techniques.

In one embodiment of the invention, the temperature of the reaction chamber of the ALD reactor can be the same throughout the entire process for manufacturing a solid electrolyte according to the invention.

In another embodiment of the invention, the temperature of the reaction chamber can vary depending on the chemical precursors injected and remaining in it. For example, during the injection and residence time of a 1^{st} chemical precursor, the temperature of the reaction chamber can be at a 1^{st} temperature, and during the injection and residence time of a 2^{nd} chemical precursor, the temperature of the reaction chamber can be at a 2^{nd} temperature.

The temperature of the reaction chamber of the ALD reactor can be comprised between 300° C. and 350° C. for the entire duration of steps b) to h).

The duration of the pulse of each of the chemical precursors implemented during the process for manufacturing an electrolyte according to the invention can be comprised between 1 second and 20 seconds.

The cumulative duration of the pulse and of the residence time in the reaction chamber of a chemical precursor implemented during the process for manufacturing an electrolyte according to the invention can be comprised between 1 second and 50 seconds.

For example, when the 1^{st} chemical precursor is LiHMDS:
the duration of the pulse of this 1^{st} chemical precursor can be comprised between 1 second and 20 seconds, for example 8 seconds;
the cumulative duration of the pulse and of the residence time in the reaction chamber of this 1^{st} chemical precursor can be comprised between 1 second and 50 seconds, for example 20 seconds.

For example, when the 2^{nd} chemical precursor is DEPA:
the duration of the pulse of this 2^{nd} chemical precursor is comprised between 1 second and 20 seconds, for example 5 seconds;
the cumulative duration of the pulse and of the residence time in the reaction chamber of this 2^{nd} chemical precursor is comprised between 1 second and 50 seconds, for example 30 seconds.

The duration of a purge step implemented during the process for manufacturing a solid electrolyte according to the invention can be comprised between 1 second and 100 seconds, for example be 35 seconds or be comprised between 2 seconds and 10 seconds.

For example, when the 1^{st} chemical precursor is LiHMDS, the duration of a purge step intended to purge this 1^{st} chemical precursor from the reaction chamber can be comprised between 1 second and 100 seconds, for example 30 seconds.

For example, when the 2^{nd} chemical precursor is DEPA, the duration of a purge step intended to purge this 2^{nd} chemical precursor from the reaction chamber can be comprised between 1 second and 100 seconds, for example 35 seconds.

As explained above, steps b) to e) are repeated or, where appropriate when step f) is carried out, steps b) to f), until a desired thickness of the solid electrolyte is obtained.

The person skilled in the art, having mastered the ALD technique perfectly, is perfectly capable of determining how many times it is necessary to repeat steps b) to e) or, where appropriate when step f) is carried out, steps b) to f), to obtain a solid electrolyte having the desired thickness.

The thickness of the solid electrolyte obtained with the manufacturing process according to the invention can be comprised between 10 nm and 30 nm.

The solid electrolyte obtained according to the manufacturing process according to the invention can be integrated into electrochemical devices, and preferably into devices selected from batteries, micro-batteries, capacitors, supercapacitors, resistors, inductors, transistors and electrochemical photovoltaic cells.

The solid electrolyte obtained according to the manufacturing process according to the invention can, for example, be integrated as reinforcement for another solid electrolyte having a micrometer thickness (i.e., less than one μm) of a battery or micro-battery. In this embodiment of the invention, the solid electrolyte is a reinforcing solid electrolyte, or in other words, an interface layer of this other solid electrolyte comprising the battery or micro-battery. This reinforcing solid electrolyte makes it possible to improve the electrochemical stability over a wide potential range, as well as the cycling performance of this other solid electrolyte.

### EXPERIMENTAL SECTION

The invention will be better understood with the aid of the detailed experimental section which is disclosed below with reference to the accompanying drawings representing:

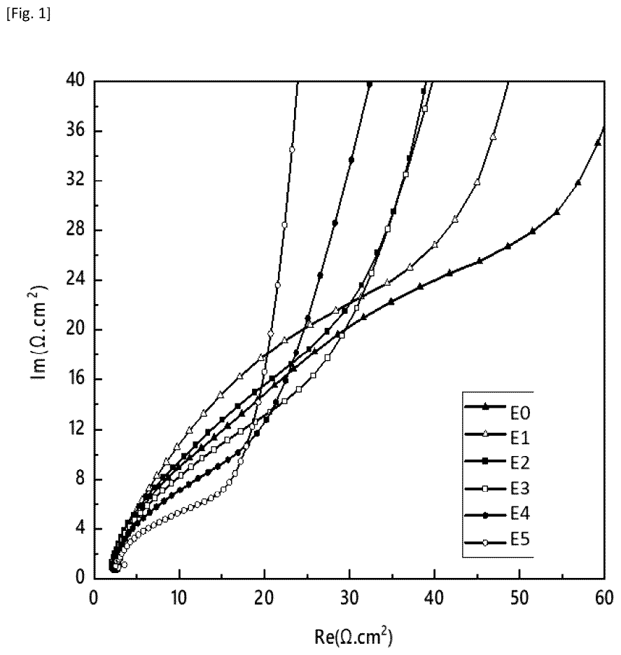

FIG. 1 represents the Nyquist diagrams established from 5 solid electrolytes obtained according to the manufacturing process according to the invention (named “E1 to E5”) and a comparative solid electrolyte named “E0”.

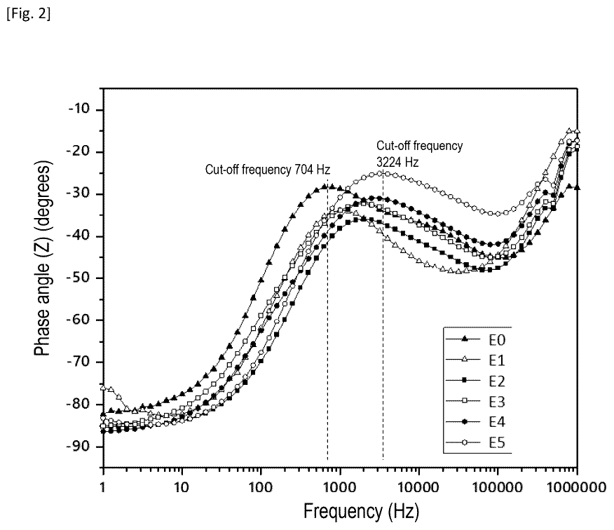

FIG. 2 represents the Bode diagrams established from these solid electrolytes E0 to E5.

5 LiPON solid electrolytes were manufactured according to the manufacturing process according to the invention by implementing for each of them the same parameters which are detailed below, with the sole exception of the parameter of the duration of step h) which differed from one solid electrolyte to another.

The substrate was a planar silicon wafer on which a MIM (MIM being the acronym for “metal-insulator-metal”) structure had been deposited.

The 1^{st} chemical precursor was LiHMDS which was stored in a bubbler at a temperature comprised between 60° C. and 80° C., for example 65° C.

The 2^{nd} chemical precursor was DEPA which was stored in a bubbler at a temperature comprised between 80° C. and 100° C., for example 95° C.

The reaction chamber was purged at each purge step with argon for a duration of 8 seconds.

The inert gas of step h) was argon.

The temperature of the reaction chamber was 330° C. throughout the entire process for manufacturing the solid electrolyte according to the invention.

The duration of the pulse of the 1^{st} chemical precursor was 8 seconds.

The duration of the pulse of the 2^{nd} chemical precursor was 5 seconds.

Step h) was carried out after all the steps of providing a pulse of a chemical precursor (namely steps b) and d)) and after all the steps of purging the reaction chamber (namely steps c) and e)).

Steps b) to e) and h) were implemented according to the parameters as detailed above and were repeated until the thickness of the solid electrolyte reached a thickness of 25 nm. This thickness corresponds to the thickness of the atomic layer thus formed by ALD.

As explained above, the duration of step h) of the manufacturing process according to the invention varied depending on the manufactured solid electrolyte. Table 1 below details the duration of step h) according to the manufactured solid electrolytes (abbreviated E1 to E5).

TABLE 1

| Solid electrolyte according to the | Duration of step h) |
|---|---|
| invention | (s) |
| E1 | 70 |
| E2 | 90 |
| E3 | 120 |
| E4 | 160 |
| E5 | 200 |

The duration of step h) was thus increased for the solid electrolytes E1 to E5.

Furthermore, a comparative solid electrolyte (abbreviated E0) was manufactured in the same way as solid electrolytes E1 to E5 with the sole exception that no step h) was implemented during its manufacture.

Next, each of the solid electrolytes E0 to E5 was disposed between two electrodes of TiN (bottom electrode) and Ti (top electrode) with a surface area of 0.02 cm² so as to constitute a lower electrode/solid electrolyte/upper electrode stack.

### I—Determination of the Ionic Conductivity of the Solid Electrolytes E0 to E5:

The ionic conductivity of the solid electrolytes E0 to E5 was determined from the lower electrode/solid electrolyte/upper electrode stacks thus obtained in the following manner.

The value of the ionic conductivity of a solid electrolyte can be obtained from a Nyquist diagram established based on impedance spectroscopy measurements of a circuit formed of a solid electrolyte disposed between two metallic electrodes.

The ionic conductivity is expressed by the following mathematical equation (1):

$$σ = {d}_{film} / [ A \times {R}_{b} ] \qquad ( 1 )$$

in which:
d_{film} corresponds to the thickness of the thin film electrolyte;
A corresponds to the surface area of the electrode;
R_{b} corresponds to the resistance of the electrolyte.

In a Nyquist diagram, the impedance is plotted as a curve with the real part of the impedance (denoted “Re”) on the x-axis and the imaginary part (denoted “Im”) on the y-axis. The impedance is expressed in ohm·cm².

FIG. 1 represents the Nyquist diagrams of the solid electrolytes E0 to E5.

As can be seen in FIG. 1, the curves have the shape of a semicircle followed by a straight (quasi-vertical) line.

For each of the electrolytes E0 to E5, the resistance R_{b} of the electrolyte was estimated by extrapolating the part of the semicircle up to the intersection with the x-axis. The values of resistance R_{b} thus estimated are detailed in Table 2 below.

A reduction in the size of the semicircle is observed for the solid electrolytes from E0 to E5. This means that the resistance R_{b} decreases, as the intersection with the x-axis is closer to the origin. Given mathematical equation (1), the reduction in resistance R_{b} implies a higher ionic conductivity.

As explained above, the thickness of the solid electrolytes E0 to E5 being 25 nm and the surface area of the electrodes being 0.02 cm², from the values of resistance Rb thus estimated and the mathematical equation (1) above, the ionic conductivity of the electrolytes E0 to E5 could be determined and is detailed in Table 2 below.

TABLE 2

| Solid electrolyte | Resistance Rb (ohm) | Ionic conductivity (S · cm⁻¹) |
|---|---|---|
| E0 | 5800 | 2.1 · 10⁻⁸ |
| E1 | 4000 | 3.1 · 10⁻⁸ |
| E2 | 3200 | 4 · 10⁻⁸ |
| E3 | 2400 | 5.2 · 10⁻⁸ |
| E4 | 1444 | 9.0 · 10⁻⁸ |
| E5 | 982 | 1.3 · 10⁻⁷ |

Based on the detailed results in Table 2, it can be seen that the ionic conductivity of the solid electrolytes according to the invention E1 to E5 is much higher than that of the comparative solid electrolyte E0. The ionic conductivity increases with increasing duration of step h) of the process for manufacturing a solid electrolyte according to the invention, from 2.1·10⁻⁸ for the solid electrolyte E0 to 1.3·10⁻⁷ for the solid electrolyte E5.

### II—Determination of the Cut-Off Frequency of the Solid Electrolytes E0 to E5:

One practical example of the use of the solid electrolytes concerns the creation of capacitances with a dual mode of operation (ionic and dielectric). Indeed, the ionic mobility determines the speed at which ions can move within the electrolyte under the influence of an applied electric field.

At low frequencies, the ions have sufficient time to migrate and form an electrochemical double layer at the electrolyte-electrode interface. As the frequency increases, the ion mobility limits their ability to follow the rapid variation of the electric field. The energy storage transitions from ionic mode to dielectric mode. Maintaining ionic behavior over a wide frequency range before the transition to the dielectric behavior is therefore crucial for maximizing the energy storage in micro-supercapacitors as an electrochemical double layer.

FIG. 2 represents the Bode diagrams established from the solid electrolytes E0 to E5. More precisely, the curves of these Bode diagrams represent the evolution of the phase angle, denoted Z, expressed in degrees, as a function of the frequency (expressed in Hz on a logarithmic scale). This allows visualization of the transition of the frequency response of the aforementioned lower electrode/solid electrolyte/upper electrode stack from an ionic regime to a dielectric regime.

The cut-off frequency corresponds to the frequency where the curve of the phase angle (Z) reaches a maximum.

Table 3 below details the cut-off frequencies thus determined from Bode diagrams for the solid electrolytes E0 to E5.

TABLE 3

| Solid electrolyte | Cut-off frequency (Hz) |
|---|---|
| E0 | 704 |
| E1 | 980 |
| E2 | 1938 |
| E3 | 1963 |
| E4 | 2920 |
| E5 | 3224 |

Based on the results detailed in Table 3, it can be seen that the cut-off frequency increases from 704 Hz for the solid electrolyte E0 to 3224 Hz for the solid electrolyte E5. These results demonstrate that the solid electrolytes obtained with the manufacturing process according to the invention are better able to transport ions at higher frequencies. This reflects an improvement in the dynamic properties of these solid electrolytes, which will lead to better overall performance, particularly in high-frequency electrochemical devices.

1. A process for manufacturing a solid electrolyte, the method comprising:
(a) disposing a substrate comprising active sites on a surface of the substrate in a reaction chamber of an atomic thin film deposition reactor;
(b) providing a pulse of a first chemical precursor, which is in gaseous form in the reaction chamber, such that the first chemical precursor reacts with the active sites of the substrate during a first chemical reaction and a first part of an atomic layer which includes active sites is formed;
(c) purging the reaction chamber of the first chemical precursor and any by-products of the first chemical reaction;
(d) providing a pulse of a second chemical precursor, which is in gaseous form in the reaction chamber, such that the second chemical precursor reacts with the active sites of the first part of the atomic layer during a second chemical reaction and a second part of the atomic layer which includes active sites is formed;
(e) purging the reaction chamber of the second chemical precursor and any by-products of the second chemical reaction;
(f) repeating steps (d) and (e) with at least one other chemical precursor;
(g) repeating steps (b) to (e), or, when step (f) is performed, steps (b) to (f), until a desired thickness of the solid electrolyte is obtained,
wherein the method further comprises performing at least once a step (h), which consists in providing a pulse of an inert gas for a determined time in the reaction chamber.

2. The manufacturing process according to claim 1, wherein the step (h) is performed before step (b).

3. The manufacturing process according to claim 1, wherein the step (h) is performed after the completion of all the purge steps or of a part of said purge steps.

4. The manufacturing process according to claim 1, wherein the step (h) is performed after the completion of all the steps during which a chemical precursor pulse is provided or of a part of the steps during which a chemical precursor pulse is provided.

5. The manufacturing process according to claim 1, wherein the step (h) is performed after all the steps of said manufacturing process where a pulse of a chemical precursor is provided and after all the purge steps.

6. The manufacturing process according to claim 1, wherein the inert gas of the step (h) is selected from nitrogen and argon.

7. The manufacturing process according to claim 1, wherein the duration of the step (h) is comprised between 10 seconds and 500 seconds.

8. The manufacturing process according to claim 1, wherein the material of the substrate is selected from titanium, platinum, nickel, ruthenium, copper, glass, silicon, and silicon carbide.

9. The manufacturing process according to claim 1, wherein the material of the solid electrolyte is selected from nitrided lithium phosphates, nitrided sodium phosphates, nitrided potassium phosphates, and nitrided magnesium phosphates.

10. The manufacturing process according to claim 9, wherein the material of the solid electrolyte is a nitrided lithium phosphate and said manufacturing process is implemented with:
a first chemical precursor selected from lithium hexamethyldisilazane, lithium tert-butylate, and lithium diethylamide; and
a second chemical precursor selected from diethyl phosphoramidate, trimethyl phosphate, tris(dimethylamino)phosphine, ammonia, and water.
